(19) United States
(12) Patent Application Publication
(10) Pub. No.: US 2016/0273092 A1
(43) Pub. Date: Sep. 22, 2016

(54) DEPOSITION APPARATUS CONTAINING MOVING DEPOSITION SOURCE

(71) Applicants: Char Lie HONG, Seongnam-si (KR); Man Ho LEE, Yongin-si (KR); BMC CO., LTD., Seongnam-si (KR)

(72) Inventors: Charlie HONG, Seongnam-si (KR); Man Ho LEE, Yongin-si (KR)

(73) Assignees: BMC CO., LTD., Seongnam-si (KR); Charlie HONG, Seongnam-si (KR); Man Ho LEE, Yongin-si (KR)

(21) Appl. No.: 14/442,268

(22) PCT Filed: Nov. 12, 2013
(86) PCT No.: PCT/KR2013/010245

§ 371 Date: May 12, 2015

(30) Foreign Application Priority Data
Nov. 15, 2012 (KR) 10-2012-0129289

(51) Int. Cl. C23C 14/24

(52) U.S. Cl. CPC C23C 14/24

(57) ABSTRACT

A deposition apparatus for depositing a thin film on a surface of a coating target within a vacuum chamber is disclosed. The deposition apparatus includes a deposition source that supplies a material for forming the thin film; a supply unit that supplies at least one of coolant, power supply, and a process gas to the deposition source; and a moving unit that moves the deposition source within the vacuum chamber.

### TECHNICAL FIELD

The present disclosure relates to a deposition apparatus containing a moving deposition source.

### BACKGROUND ART

When manufacturing liquid crystal displays and organic light emitting displays, a transparent electrode, a metal electrode, an insulating film, etc., are formed through a physical vapor deposition (PVD) method or a chemical vapor deposition (CVD) methods such as a plasma enhanced chemical vapor deposition (PECVD) method.

A conventional physical or chemical vapor deposition apparatus uses a method of fixing a deposition source and moving or spinning a coating target. Since the deposition source should be connected to various devices for supplying coolant, power supply, a process gas, etc., it should be necessarily in the fixed form.

However, in case of depositing a thin film on a coating target in a bent form through the deposition apparatus containing the fixed deposition source, a distance between a surface of the coating target and the deposition source varies depending on the position of the coating target. Accordingly, there has been a problem in that it is difficult to form a uniform thin film. Also, there has been a problem in that the movement of the coating target generates particles.

Thus, a deposition apparatus, which can form a uniform thin film on a coating target in any shape and minimize the generation of the particles, is being demanded.

### DISCLOSURE OF THE INVENTION

### Problems to be Solved by the Invention

The present disclosure provides a deposition apparatus, which can form a uniform thin film on coating targets in various shapes and minimize generation of particles resulting from movement of the coating targets.

### Means for Solving the Problems

In accordance with the illustrative embodiment, there is provided an a deposition apparatus for depositing a thin film on a surface of a coating target within a vacuum chamber, including a deposition source that supplies a material for forming the thin film; a supply unit that supplies at least one of coolant, power supply, and a process gas to the deposition source; and a moving unit that moves the deposition source within the vacuum chamber.

In the present disclosure, wherein the supply unit is provided within the vacuum chamber, and, the deposition apparatus further includes a particle shield that is provided between the deposition source and the supply unit to separate the supply unit from the deposition source.

### Effect of the Invention

According to the foregoing technical means of the present disclosure, it is possible to form a more uniform thin film and minimize generation of particles resulting from movement of a coating target, by fixing the coating target and moving the deposition source to control a distance between a surface of the coating target and the deposition source.

Also, it is possible to effectively prevent introduction of residual deposition materials into the supply unit resulting in generation of particles and introduction of particles into the coating target resulting in contamination of the surface of the coating target, by separating the supply unit from the deposition source through the particle shield in the inside of the vacuum chamber.

### BRIEF DESCRIPTION OF THE DRAWINGS

FIG. 1 is a conceptual diagram of a deposition apparatus in accordance with an illustrative embodiment of the present disclosure.

FIG. 2 is a schematic cross-sectional view of a side of a deposition apparatus in accordance with an illustrative embodiment of the present disclosure.

FIGS. 3 and 4 are conceptual diagrams for depiction of other illustrative embodiments of a moving unit.

FIG. 5 depicts the case where a deposition source contains multiple cathodes.

FIG. 6 shows various illustrative embodiments of the deposition source containing the multiple cathodes in FIG. 5.

FIG. 7 depicts the case where the deposition source is provided with circular cathode.

FIG. 8 depicts the case where the deposition source is a PECVD deposition source.

FIG. 9 depicts various movement routes of the deposition source through a moving unit and a spinning unit.

FIG. 10 depicts a deposition source having a shutter.

FIG. 11 shows the deposition apparatus of FIG. 2, in which a deposition source and a coating target are positioned to be inclined while being sloping downward.

### BEST MODE FOR CARRYING OUT THE INVENTION

Hereinafter, illustrative embodiments of the present disclosure will be described in detail with reference to the accompanying drawings so that inventive concept may be readily implemented by those skilled in the art. However, it is to be noted that the present disclosure is not limited to the illustrative embodiments but can be realized in various other ways. In the drawings, certain parts not directly relevant to the description are omitted to enhance the clarity of the drawings, and like reference numerals denote like parts throughout the whole document.

Throughout the whole document, the term “on” that is used to designate a position of one element with respect to another element includes both a case that the one element is adjacent to the another element and a case that any other element exists between these two elements.

Throughout the whole document, the term “comprises or includes” and/or “comprising or including” used in the document means that one or more other components, steps, operations, and/or the existence or addition of elements are not excluded in addition to the described components, steps, operations and/or elements. Throughout the whole document, the terms “about or approximately” or “substantially” are intended to have meanings close to numerical values or ranges specified with an allowable error and intended to prevent accurate or absolute numerical values disclosed for understanding of the present invention from being illegally or unfairly used by any unconscionable third party. Throughout the whole document, the term “step of” does not mean “step for”.

Through the whole document, the term “combination of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

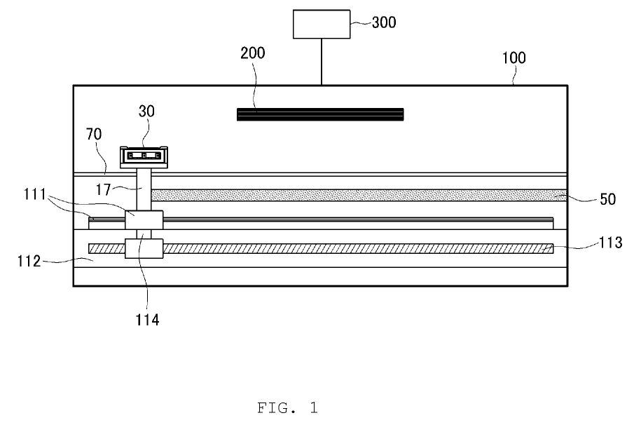

Additionally, the terms related to directions or positions (upward, downward, an upward and downward direction, a left side, a right side, a right and left direction, etc.) in the descriptions of illustrative embodiments of the present disclosure have been set based on the state of the positions of the respective elements illustrated in the drawings. For example, in FIG. 1, the upper part may refer to an upper side, the lower part may refer to a lower side, the left part may refer to a left side, and the right part may refer to a right side. However, in various actual applications of illustrative embodiments of the present disclosure, the elements can be positioned in various directions, and for example, the upper and lower sides, and the left and right sides may be reversed.

Hereinafter, the present disclosure is described in detail with reference to the accompanying drawings.

First, a deposition apparatus in accordance with an illustrative embodiment of the present disclosure (hereinafter referred to as the “present deposition apparatus”) is described.

The present deposition apparatus 1000 contains a deposition source 30.

The deposition source 30 supplies a material for forming a thin film. In this case, the material supplied by the deposition source 30 may include metal, ceramic, and a polymer material.

In addition, the deposition source 30 may be contained in a physical vapor deposition apparatus such as sputtering and an e-beam, or a chemical vapor deposition apparatus such as PECVD, MOCVD, and LPCVD.

The deposition source 30 may be positioned in various forms. For example, in the case where the deposition source 30 and a coating target 200 are positioned in the left and right direction as illustrated in FIG. 1, it is possible to prevent a surface of the coating target 200 from being contaminated by particles generated from introduction of a material into a supply unit 50.

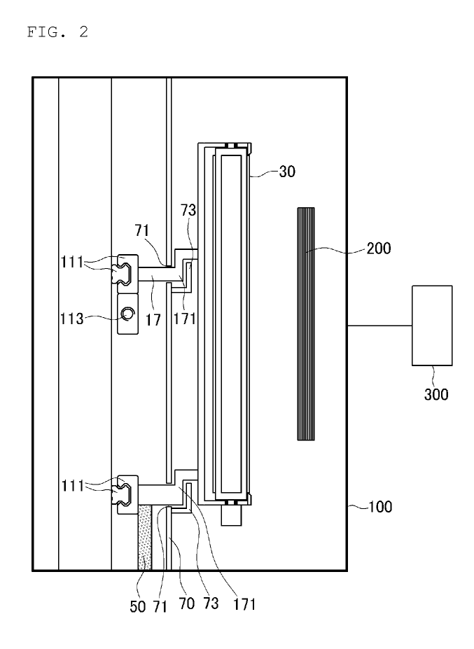

For another illustrative embodiment, in the case where the deposition source 30 and the coating target 200 are positioned in the upward and downward direction as illustrated in FIG. 2, it is possible to prevent a material from being introduced into the supply unit 50. As a result, it is possible to suppress the generation of the particles that contaminate the surface of the coating target 200.

The deposition source 30 and the coating target 200 may be positioned to be inclined while being sloping downward. This is intended to minimize the influence of the particles to the surface of the coating target 200.

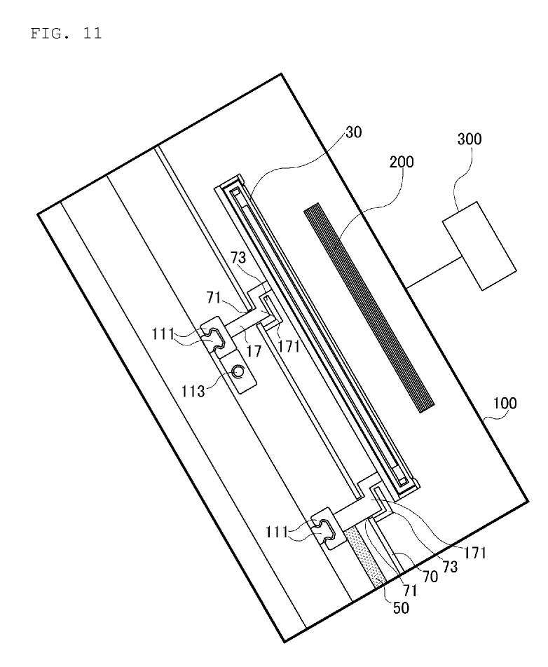

In the case where the deposition source 30 and the coating target 200 are positioned in the upward and downward direction, while the surface of the coating target 200 is inclined to slightly face the gravity direction as illustrated in FIG. 11, it is possible to effectively prevent a material from being introduced into the supply unit 50 and particles generated from the supply unit 50 from being introduced onto the surface of the coating target 200. As a result, it is possible to minimize contamination of the surface of the coating target 200.

The present deposition apparatus 1000 contains the supply unit 50.

The supply unit 50 supplies at least one of coolant, power supply, and a process gas to the deposition source 30.

The supply unit 50 may be provided within a vacuum chamber 100.

In this case, it is preferable that the supply unit 50 is provided to prevent coolant, power supply, and a process gas from being leaked or discharged in the inside of the vacuum chamber 100.

To be more specific, there is a risk that a part of the supply unit 50 for supplying coolant leaks the coolant due to pressure difference from existing water pressure caused from specificity of the inside of the vacuum chamber, and low precision of material quality. Accordingly, it is preferable to use precise quality of a material for the supply unit 50, and avoid leakage at connecting parts.

In addition, in case of a part of the supply unit 50 for supplying power supply, in order to prevent dielectric breakdown occurring in a vacuum area, it is preferable to use a wire formed with a certain or higher insulation grade of sheath, and thereby, suppressing the occurrence of the dielectric breakdown especially at connecting parts.

The present deposition apparatus 1000 contains a moving unit 10.

The moving unit 10 moves the deposition source 30 within the vacuum chamber 100.

A deposition rate of a thin film varies depending on a distance between the deposition source and the coating target. However, in a conventional deposition apparatus, a deposition source is fixed, and thus, when a thin film is formed on a surface of a coating target in a curved shape, the distance between the coating target and the deposition source cannot be controlled to be consistent. Accordingly, the conventional deposition apparatus has had a problem in that it could not form a uniform thin film on coating targets in various shapes.

To the contrary, the present deposition apparatus 100 can control the distance between the surface of the coating target 200 and the deposition source 30 to be consistent, by fixing the coating target 200 and moving the deposition source 30. Accordingly, the present deposition apparatus 100 can form a more uniform thin film on coating targets 200 in various shapes. Further, the present deposition apparatus 100 can minimize the generation of the particles resulting from the movement of the coating target 200.

The moving unit 10 may contain a first moving section 11. The first moving section 11 can move the deposition source 30 along a route.

In this case, the route may be formed in parallel with the surface of the coating target 200 to consistently maintain the distance between the deposition source 30 and the coating target 200.

This is intended to form a consistent and uniform thin film on the whole surface of the coating target 200.

For example, with reference to FIG. 1, in case of the coating target 200 in a flat shape, the first moving section 11 can consistently maintain the distance between the surface of the coating target 200 and the deposition source 30, by moving the deposition source 30 in a linear form.

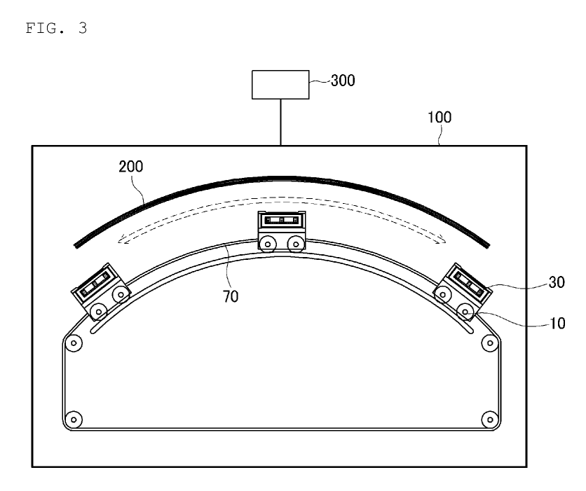

For another illustrative embodiment, with reference to FIG. 3, in case of the coating target 200 in a bent shape, the first moving section 11 can consistently maintain the distance between the surface of the coating target 200 and the deposition source 30, by moving the deposition source 30 along a route corresponding to the shape of the surface of the coating target 200.

The moving unit 10 may contain a connecting member 17. With reference to FIGS. 1, 2 and 4, the connecting member 17 may be connected to the deposition source 30.

The first moving section 11 may contain a first linear motion section 111. The first linear motion section 111 can move the connecting member 17 along a route.

With reference to FIG. 2, the first linear motion section 111 may be provided with a block for enabling the movement of the connecting member 17 and a guide rail for guiding a route of the block. However, the first linear motion section 111 is not limited thereto and may be provided in various forms.

With reference to FIGS. 1, 2 and 4, the first linear motion section 111 may be supported by a first support 112.

The first moving section 11 may contain a first power section 113. The first power section 113 can supply power to the first linear motion section 111.

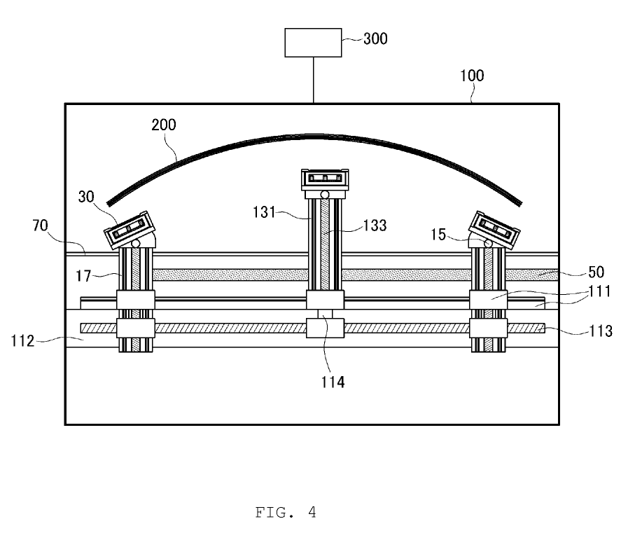

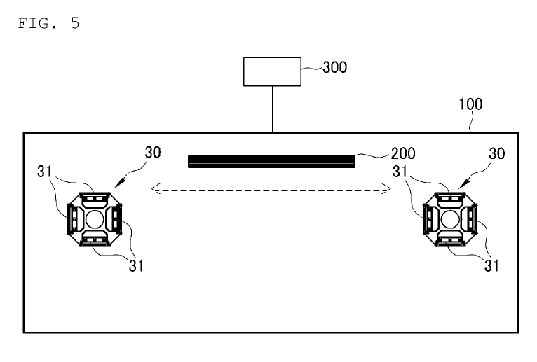

For example, as illustrated in FIGS. 1 and 4, the first power section 113 may be provided below the first linear motion section 111. In this case, the power generated in the first power section 113 can be transferred by a first power transfer section 114 to the first linear motion section 111.

For another illustrative embodiment, the first power section 113 may be provided on a side of the block contained in the first linear motion section 111. However, the position of the first power section 113 is not limited thereto, and the first power section 113 may be in various positions.

It is preferable that the first power section 113 is configured to be usable in the inside of the vacuum chamber 100. For example, the first power section 113 may contain a linear motor, a ball screw, a rack pinion, a chain, a belt, or others.

The moving unit 10 may contain a second moving section 13. The second moving section 13 can control the distance between the deposition source 30 and the coating target 200.

With reference to FIG. 4, the second moving section 13 can enable a thin film having a uniform thickness to be formed on the surface of the coating target 200, by moving the position of the deposition source 30 to consistently maintain the distance between the deposition source 30 and the coating target 200.

The second moving section 13 may contain a second linear motion section 131. The second linear motion section 131 can control the distance between the deposition source 30 and the coating target 200 by moving the connecting member 17.

The second linear motion section 131 may be provided with a block for enabling the movement of the connecting member 17 and a guide rail for guiding a route of the block. However, the second linear motion section 131 is not limited thereto and may be provided in various forms.

The second moving section 13 may contain a second power section 133. The second power section 133 can supply power to the second linear motion section 131.

It is preferable that the second power section 133 is configured to be usable in the inside of the vacuum chamber 100. For example, the second power section 133 may contain a linear motor, a ball screw, a rack pinion, a chain, a belt, or others.

The moving unit 10 may contain a spinning unit 15.

With reference to FIG. 4, the spinning unit 15 can spin the deposition source 30 based on a single axis in parallel with the surface of the coating target 200 as a spinning axis. In this case, the spinning axis may be orthogonal to the route, in which the deposition source 30 is moved.

In this case, the deposition source 30 and the coating target 200 in any shape can be maintained while having an equal distance. Accordingly, it is possible to form a uniform thin film on a coating target 200 in any shape.

The deposition source 30 may contain multiple cathodes 31, which are arranged along a circumference of the spinning axis.

Since the present deposition apparatus 1000 has the structure, which moves the deposition source 30 within the vacuum chamber 100, the dimension of the deposition apparatus 1000 is significantly affected by the dimension of the deposition source 30.

Accordingly, in order to minimize the dimension of the deposition apparatus 1000, the multiple cathodes 31 are contained in the single deposition source 30, and not multiple deposition sources 30 are provided, such that the deposition source 30 spins through the spinning unit 15, and thereby, making better use of the space of the deposition source 30. As a result, the dimension of the deposition apparatus 1000 can be minimized.

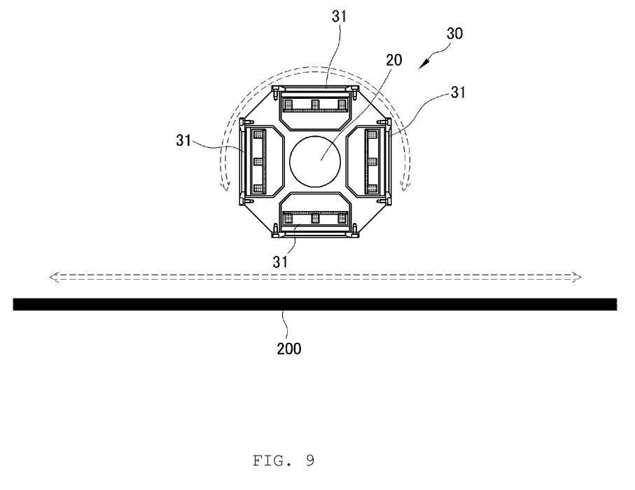

With reference to FIG. 9, it is possible to change the cathode 31 facing the surface of the coating target 200 depending on a material for a thin film desired to be formed, by spinning the deposition source 30 through the spinning unit 15. Accordingly, it is unnecessary to separately provide the deposition source 30 for each material.

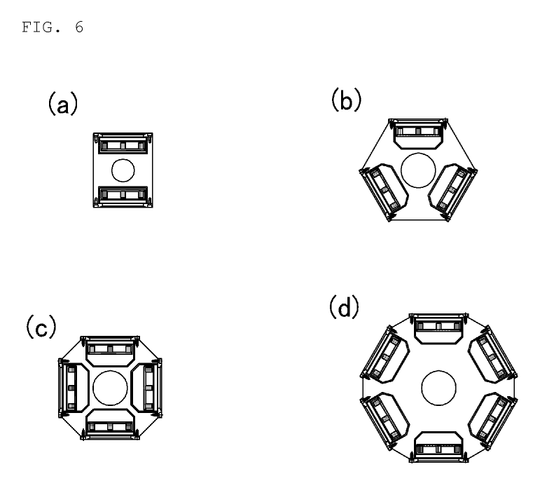

With reference to FIG. 6, the deposition source 30 may contain the variety number of the cathodes 31 according to necessity.

In this case, the multiple cathodes 31 may supply different materials, respectively.

In case of forming various types of thin films, it is possible to enable the multiple cathodes 31 to alternatively supply materials, by spinning the deposition source 30 through the spinning unit 15.

In this case, the multiple cathodes 31 may supply different materials respectively, or only parts of the multiple cathodes 31 may supply different materials. For example, when the deposition source 30 contains four cathodes 31, the four cathodes 31 may supply different materials, or two of the four cathodes 31 may supply the same material, and the other two of the cathodes 31 may supply different materials.

The deposition source 30 may contain a shutter 33 along the circumference of the spinning axis to enable only the cathode 31 supplying a material toward the coating target 300, among the multiple cathodes 31, to be exposed outward.

In the case where the multiple cathodes 31 supply different materials respectively, or only parts of the multiples cathodes 31 supply different materials, a material supplied by a cathode may be introduced into another cathode supplying a different material during the supply of the materials, and thereby, contaminating the cathodes 31.

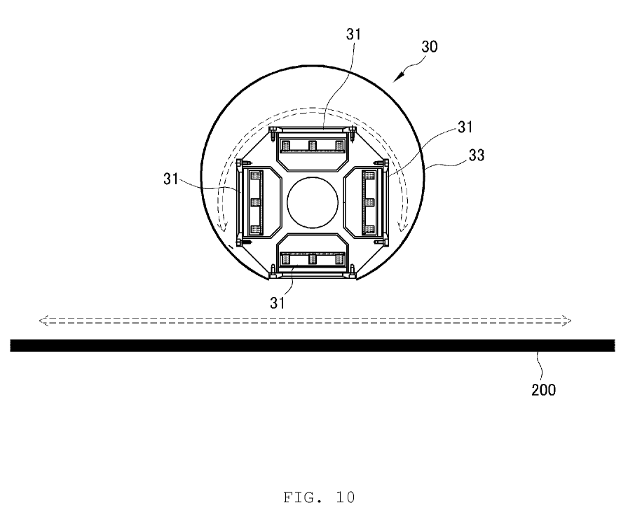

Accordingly, as illustrated in FIG. 10, the present deposition apparatus 1000 can prevent the contamination of the cathodes 31, by preventing a material supplied by the cathode 31 to be exposed outward from being introduced into another cathode 31 supplying a different material through the shutter 33.

As described above, in the deposition source 30, the multiple cathodes 31 may be arranged along the circumference of the spinning axis, or be positioned on the same plane.

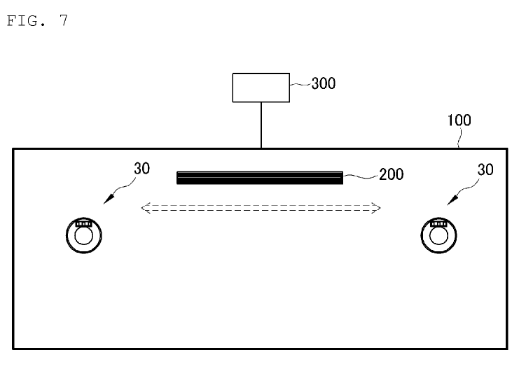

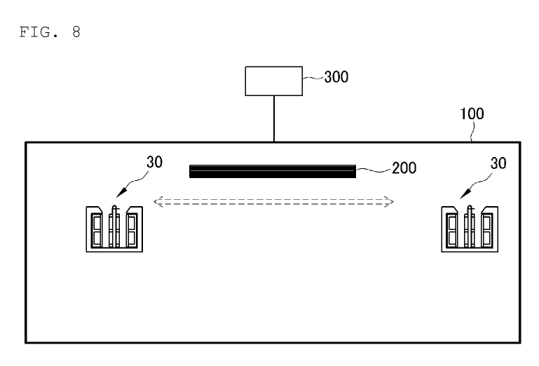

In addition, as illustrated in FIG. 7, the deposition source 30 may be provided with the cathode 31 in a circular shape. As illustrated in FIG. 8, the deposition source 30 may be applicable to PECVD.

The present deposition apparatus 1000 may contain a particle shield 70.

The particle shield 70 may be provided between the deposition source 30 and the supply unit 50 to separate the supply unit 50 from the deposition source 30.

Unlike a conventional deposition apparatus, in the case where the coating target 200 is fixed, and the deposition source 30 is moved, the supply unit 50 for supplying coolant, power supply and a process gas to the deposition source 30 is provided in the inside of the vacuum chamber 100. In this case, when part of a material supplied by the deposition source 30 is introduced into the moving unit 10 or the supply unit 50, the moving unit 10 or the supply unit 50 becomes a particle generating source. When the generated particles are introduced into the coating target 200, the surface of the coating target 200 may be contaminated.

Accordingly, as illustrated in FIGS. 1 to 3, it is possible to prevent a material supplied by the deposition source 30 from being introduced into the supply unit 50 or the moving unit 10, and the generated particles from being introduced into the coating target 200, by separating the supply unit 50 from the deposition source 30 through the particle shield 7. As a result, it is possible to prevent the contamination of the surface of the coating target 200.

The particle shield 70 is provided with a slot 71 to enable the movement of the connecting member 17.

With reference to FIG. 2, the slot 71 may be formed along the route, in which the connecting member 17 is moved. In this case, in order to prevent materials and particles from being moved through the slot 71, the slot 71 is preferably formed in a size as minimal as possible to only enable the movement of the connecting member 17.

The particle shield 70 may contain an auxiliary shield 73 protruded from a periphery of the slot 71.

The auxiliary shield 73 can prevent deposition materials from being introduced into the supply unit 50 through the slot 71.

In addition, the auxiliary shield 73 can prevent particles from being introduced into the surface of the coating target 200 through the slot 71.

In this case, it is preferable that the auxiliary shield 73 is protruded and inclined toward the slot 71 as much as possible such that materials and particles cannot be moved through the slot 71, while not interrupting the movement of the connecting member 71.

The auxiliary shield 73 may be of a “ [symbol] ” shape bent to cover the slot 71.

In this case, the connecting member 17 may contain a bent section 171, which is in a bent form corresponding to the auxiliary shield 73.

With reference to FIG. 2, movement of materials supplied from the deposition source 30 and particles generated from the supply unit 50 can be effectively blocked through the auxiliary shield 73 and the bent section 171, which are in the bent form. Accordingly, generation of particles and contamination of the surface of the coating target 200 can be minimized.

The present deposition apparatus 1000 can control and consistently maintain the distance between the surface of the coating target 200 and the deposition source 30 by fixing the coating target 200 and moving the deposition source 30. Accordingly, the present deposition apparatus 1000 can form a more uniform thin film and minimize generation of particles resulting from the movement of the coating target 200.

In addition, the present deposition apparatus 1000 can effectively prevent introduction of residual deposition materials into the supply unit 50 resulting in generation of particles and introduction of the particles into the coating target resulting in contamination of the surface of the coating target 200, by separating the supply unit 50 from the deposition source 30 in the inside of the vacuum chamber 100 through the particle shield 70.

The above description of the illustrative embodiments is provided for the purpose of illustration, and it would be understood by those skilled in the art that various changes and modifications may be made without changing technical conception and essential features of the illustrative embodiments. Thus, it is clear that the above-described illustrative embodiments are illustrative in all aspects and do not limit the present disclosure. For example, each component described to be of a single type can be implemented in a distributed manner. Likewise, components described to be distributed can be implemented in a combined manner.

The scope of the inventive concept is defined by the following claims and their equivalents rather than by the detailed description of the illustrative embodiments. It shall be understood that all modifications and embodiments conceived from the meaning and scope of the claims and their equivalents are included in the scope of the inventive concept.

What is claimed is:

1. A deposition apparatus for depositing a thin film on a surface of a coating target within a vacuum chamber, the apparatus comprising:
a deposition source that supplies a material for forming the thin film;
a supply unit that supplies at least one of coolant, power supply, and a process gas to the deposition source; and
a moving unit that moves the deposition source within the vacuum chamber.

2. The deposition apparatus of claim 1,
wherein the moving unit includes a first moving section that moves the deposition source along a route.

3. The deposition apparatus of claim 2,
wherein the route is formed in parallel with the surface of the coating target to consistently maintain a distance between the deposition source and the coating target.

4. The deposition apparatus of claim 2,
wherein the moving unit comprises a connecting member that is connected to the deposition source, and
the first moving section includes a first linear motion section that moves the connecting member along the route, and a first power section that supplies power to the first linear motion section.

5. The deposition apparatus of claim 4,
wherein the moving unit includes a second moving section that controls a distance between the deposition source and the coating target.

6. The deposition apparatus of claim 5,
wherein the second moving section includes
a second linear motion section that moves the connecting member to control the distance between the deposition source and the coating target, and
a second power section that supplies power to the second linear motion section.

7. The deposition apparatus of claim 2,
wherein the moving unit includes
a spinning unit that spins the deposition source based on a single axis in parallel with the surface of the coating target as a spinning axis.

8. The deposition apparatus of claim 7,
wherein the spinning axis is orthogonal to the route.

9. The deposition apparatus of claim 7,
wherein the deposition source includes a plurality of cathodes arranged along a circumference of the spinning axis.

10. The deposition apparatus of claim 9,
wherein the plurality of the cathodes supply different materials, respectively.

11. The deposition apparatus of claim 9,
wherein the deposition source has a shutter along the circumference of the spinning axis to enable only a cathode supplying a material toward the coating target, among the plurality of the cathodes, to be exposed outward.

12. The deposition apparatus of claim 7,
wherein the deposition source is provided with a circular cathode.

13. The deposition apparatus of claim 4,
wherein the supply unit is provided within the vacuum chamber, and
the deposition apparatus further includes a particle shield that is provided between the deposition source and the supply unit to separate the supply unit from the deposition source.

14. The deposition apparatus of claim 13,
wherein the particle shield is provided with a slot to enable movement of the connecting member.

15. The deposition apparatus of claim 14,
wherein the particle shield further includes
an auxiliary shield that is protruded from a peripheral of the slot to prevent the material from being introduced into the supply unit or particles from being introduced onto the surface of the coating target.

16. The deposition apparatus of claim 15,
wherein the auxiliary shield is of a “ [symbol] ” shape being bent to cover the slot.

17. The deposition apparatus of claim 16,
wherein the connecting member includes a bent section that is in a bent form corresponding to the auxiliary shield.

18. The deposition apparatus of claim 1,
wherein in order to minimize influence of particles to the surface of the coating target, the deposition source and the coating target are provided to be inclined while being sloping downward.
